(19) United States
(12) Patent Application Publication
(10) Pub. No.: US 2011/0033957 A1
(43) Pub. Date: Feb. 10, 2011

(54) INTEGRATED THIN FILM METROLOGY SYSTEM USED IN A SOLAR CELL PRODUCTION LINE

(75) Inventors: James Matthew Holden, San Jose, CA (US); Edward W. Budiarto, Fremont, CA (US); Karen Lingel, Union City, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/851,063

(22) Filed: Aug. 5, 2010

Related U.S. Application Data
(60) Provisional application No. 61/232,336, filed on Aug. 7, 2009.

(51) Int. Cl. H01L 21/66; B05C 11/00; G01B 11/24

(52) U.S. Cl. 438/16; 118/712; 356/601; 257/E21.529

(57) ABSTRACT

Embodiments of the present invention generally relate to systems, apparatuses, and methods used to form solar cell devices using processing modules adapted to perform one or more processes in the formation of the solar cell devices. In one embodiment, the system provides an inline inspection system of solar cell devices within a solar cell production line while collecting and using metrology data to diagnose, tune, or improve production line processes during manufacture of solar cell devices. In one embodiment, the inspection system provides an on-the-fly characterization module positioned downstream from one or more processing tools wherein the characterization module is configured to measure on-the-fly one or more properties of one or more photovoltaic layers formed on a substrate surface and a system controller in communication with the characterization module and the one or more processing tools, where the system controller is configured to analyze information received from the characterization module.

### CROSS-REFERENCE TO RELATED APPLICATIONS

This application claims benefit of U.S. Provisional Patent Application Ser. No. 61/232,336 (APPM/014352L), filed Aug. 7, 2009, which is herein incorporated by reference. This application is related to U.S. application Ser. No. 12/202,199, filed Aug. 29, 2008 (Attorney Docket No. APPM/11141), U.S. application Ser. No. 12/201,840, filed Aug. 29, 2008 (Attorney Docket No. APPM/11141.02), and U.S. application Ser. No. 12/698,559 filed Feb. 2, 2010 (Attorney Docket No. APPM/13847).

### BACKGROUND OF THE INVENTION

1. Field of the Invention

Embodiments of the present invention generally relate to a suite of modules for quality inspection and collection of metrology data during a solar cell device manufacturing process performed in a production line.

2. Description of the Related Art

Photovoltaic (PV) devices or solar cells are devices which convert sunlight into direct current (DC) electrical power. Typical thin film type PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Typically, a thin film solar cell includes active regions, or photoelectric conversion units, and a transparent conductive oxide (TCO) film disposed as a front electrode and/or as a backside electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (pc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers. There is a need for an improved process of forming a solar cell that has good interfacial contact, low contact resistance, and high overall performance.

With traditional energy source prices on the rise, there is a need for a low cost way of producing electricity using a low cost solar cell device. Conventional solar cell manufacturing processes are highly labor intensive and have numerous interruptions that can affect the production line throughput, solar cell cost, and device yield. For instance, conventional quality inspection of solar cell devices is typically either only conducted on fully formed solar cell devices via performance testing or on partially formed solar cell devices that are manually removed from the production line and inspected. Neither inspection scheme provides metrology data to assure the quality of the solar cell devices and diagnose or tune production line processes during manufacturing of the solar cell devices.

Therefore, there is a need for a production line having a suite of modules strategically placed to provide inspection of solar cell devices at various levels of formation, while collecting and using metrology data to diagnose, tune, or improve production line processes during the manufacture of solar cell devices.

### SUMMARY OF THE INVENTION

In one embodiment of the present invention, an inline inspection system within an automated solar cell production line is provided. The inspection system includes one or more processing tools, a substrate reader positioned upstream from the one or more processing tools, a characterization module positioned downstream from one or more processing tools, wherein the characterization module is configured to measure on-the-fly one or more properties of one or more photovoltaic layers formed on a substrate surface, and a system controller in communication with the reader, the characterization module, and the one or more processing tools, the system controller configured to analyze information received from the characterization module.

In another embodiment of the present invention, a characterization module includes a housing frame configured to be positioned along a solar cell production line, a light source attached to the frame and configured to illuminate moving substrates on-the-fly as the substrates move along the solar cell production line, and at least one spectral imaging sensor attached to the frame and configured to receive on-the-fly any of reflected, refracted, and transmitted light from an illuminated moving substrate.

In yet another embodiment of the present invention, a method for inspecting a substrate in a solar cell production line includes processing the substrate to form one or more photovoltaic layers on the substrate, passing the substrate having the one or more photovoltaic layers through a characterization module, measuring on-the-fly one or more properties of the one or more photovoltaic layers, and determining whether to take a corrective action.

In yet another embodiment of the present invention, an inline inspection system includes a first processing tool to deposit a top photovoltaic junction on a substrate surface in a solar cell production line, a first characterization module positioned downstream from the first processing tool to measure the properties of the top photovoltaic junction, a second processing tool to deposit a bottom photovoltaic junction on the substrate surface, a second characterization module positioned downstream from the first processing tool, the first characterization module, and the second processing tool to measure the properties of the bottom photovoltaic junction, and a system controller in communication with the first and second characterization module and the one or more processing tools, the system controller configured to analyze information received from the first and second characterization module.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device according to one embodiment described herein.

FIG. 2 illustrates a plan view of a solar cell production line according to one embodiment described herein.

FIG. 3A is a side cross-sectional view of a thin film solar cell device according to one embodiment described herein.

FIG. 3B is a side cross-sectional view of a thin film solar cell device according to one embodiment described herein.

FIG. 3C is a plan view of a composite solar cell structure according to one embodiment described herein.

FIG. 3D is a side cross-sectional view along Section 3D-3D of FIG. 3C.

FIG. 3E is a side cross-sectional view of a thin film solar cell device according to one embodiment described herein.

FIG. 4 illustrates a schematic view of one embodiment of the various control features that may be contained within the system controller.

FIG. 5 illustrates a plan view of a portion of a solar cell production line shown in FIG. 2.

FIGS. 6A and 6B are a plan view of substrates on an automation device passing over a light source of a characterization module according to one embodiment of described herein.

FIG. 6C is a plan view of a substrate orientation as it may travel on an automation device as illustrated in FIGS. 6A and 6B.

FIG. 7 is an isometric view of a characterization module according to one embodiment described herein.

FIG. 8A is a side view of a characterization module as depicted in FIG. 7.

FIG. 8B is another side view of the characterization module as depicted in FIG. 7.

FIG. 9 is a schematic depiction of the light transmitted from the light source to the spectral imaging sensor.

FIG. 10 depicts an exemplary measurement pattern on a moving substrate according to one embodiment described herein

FIGS. 11A-11C depict schematic partial cross-sectional view of a photovoltaic layers on substrate that are inspected according to one embodiment described herein.

FIG. 12 illustrates a method of inspecting a substrate in a solar cell production line according to one embodiment described herein.

FIG. 13 illustrates a data array according to one embodiment of the invention.

### DETAILED DESCRIPTION

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, sectioning, bonding, and various inspection and testing processes to form multiple complete, functional, and tested solar cell devices that can then be shipped to an end user for installation in a desired location to generate electricity. In one embodiment, the system provides inspection of solar cell devices at various levels of formation, while collecting and using metrology data to diagnose, tune, or improve production line processes during the manufacture of solar cell devices. While the discussion below primarily describes the formation of silicon thin film solar cell devices, this configuration is not intended to be limiting as to the scope of the invention since the apparatus and methods disclosed herein can also be used to form, test, and analyze other types of solar cell devices, such as III-V type solar cells, thin film chalcogenide solar cells (e.g., CIGS, CdTe cells), amorphous or nanocrystalline silicon solar cells, photochemical type solar cells (e.g., dye sensitized), crystalline silicon solar cells, organic type solar cells, or other similar solar cell devices.

The system is generally an arrangement of automated processing modules and automation equipment used to form solar cell devices that are interconnected by an automated material handling system. In one embodiment, the system is a fully automated solar cell device production line that reduces or removes the need for human interaction and/or labor intensive processing steps to improve the solar cell device reliability, production process repeatability, and the cost of ownership of the solar cell device formation process. In one configuration, the system generally comprises a substrate receiving module that is adapted to accept an incoming substrate, one or more absorbing layer deposition cluster tools having at least one processing chamber that is adapted to deposit a silicon-containing layer on a processing surface of the substrate, one or more back contact deposition chambers that is adapted to deposit a back contact layer on the processing surface of the substrate, one or more material removal chambers that are adapted to remove material from the processing surface of each substrate, one or more sectioning modules used to section the processed substrate into multiple smaller processed substrates, a solar cell encapsulation device, an autoclave module that is adapted to heat and expose a composite solar cell structure to a pressure greater than atmospheric pressure, a junction box attaching region to attach a connection element that allows the solar cells to be connected to external components, a suite of inspection modules adapted to inspect each solar cell device at various levels of formation, and one or more quality assurance modules adapted to test and qualify each completely formed solar cell device. In one embodiment, the inspection modules includes one or more characterization modules configured to collect metrology data and communicate the data to a system controller to diagnose, tune, improve, and/or assure quality processing within the solar cell device production system.

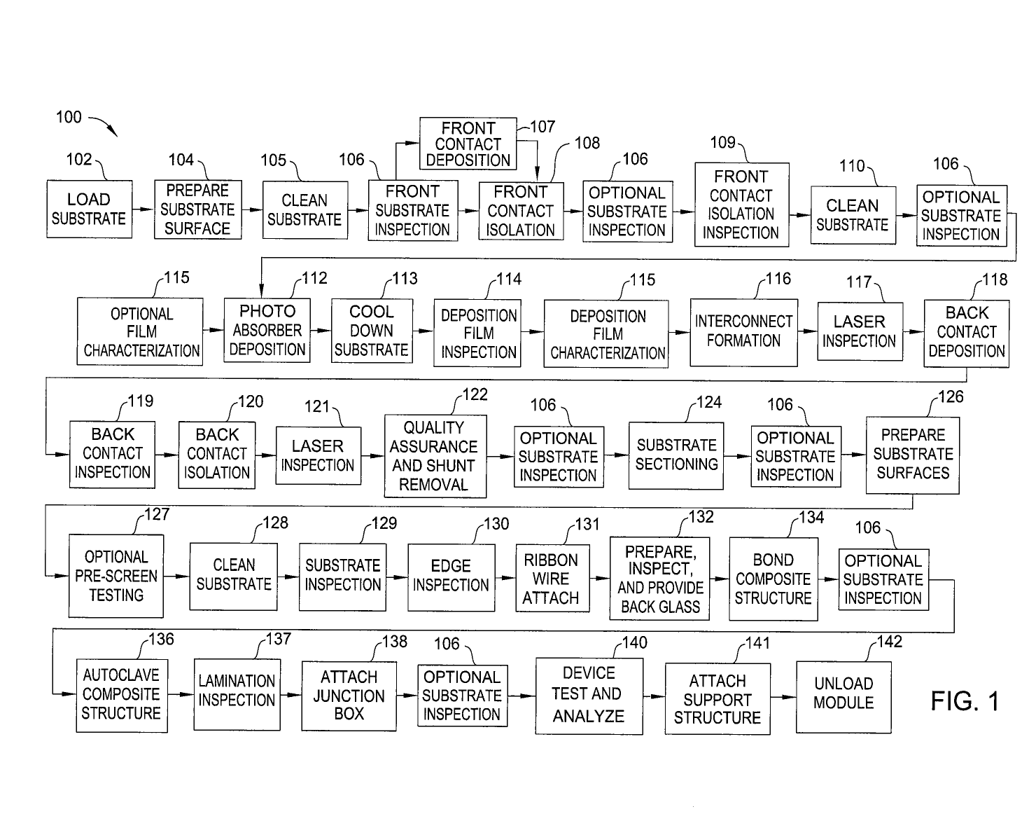

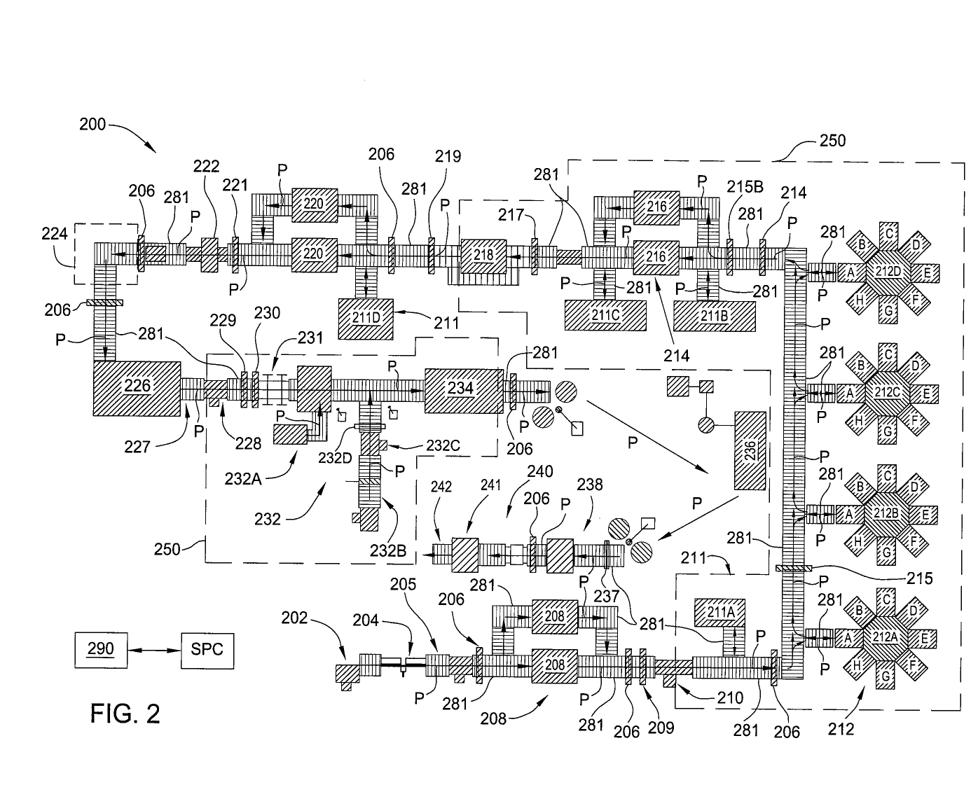

FIG. 1 illustrates one embodiment of a process sequence 100 that contains a plurality of steps (i.e., steps 102-142) that are each used to form a solar cell device using a novel solar cell production line 200 described herein. The configuration, number of processing steps, and order of the processing steps in the process sequence 100 is not intended to be limiting to the scope of the invention described herein. FIG. 2 is a plan view of one embodiment of the production line 200, which is intended to illustrate some of the typical processing modules and process flows through the system and other related aspects of the system design, and is thus not intended to be limiting to the scope of the invention described herein.

In general, a system controller 290 may be used to control one or more components found in the solar cell production line 200. The system controller 290 is generally designed to facilitate the control and automation of the overall solar cell production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the solar cell production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete solar cell production line. In one embodiment, the system controller includes local controllers disposed in inspection modules to map and evaluate defects detected in each substrate as it passes through the production line 200 and determine whether to allow the substrate to proceed or reject the substrate for corrective processing or scrapping. An example of a system controller, distributed control architecture, and other system control structure that may be useful for one or more of the embodiments described herein can be found in the U.S. patent application Ser. No. 12/202,199 [Atty. Dkt. No. 11141], which is incorporated by reference.

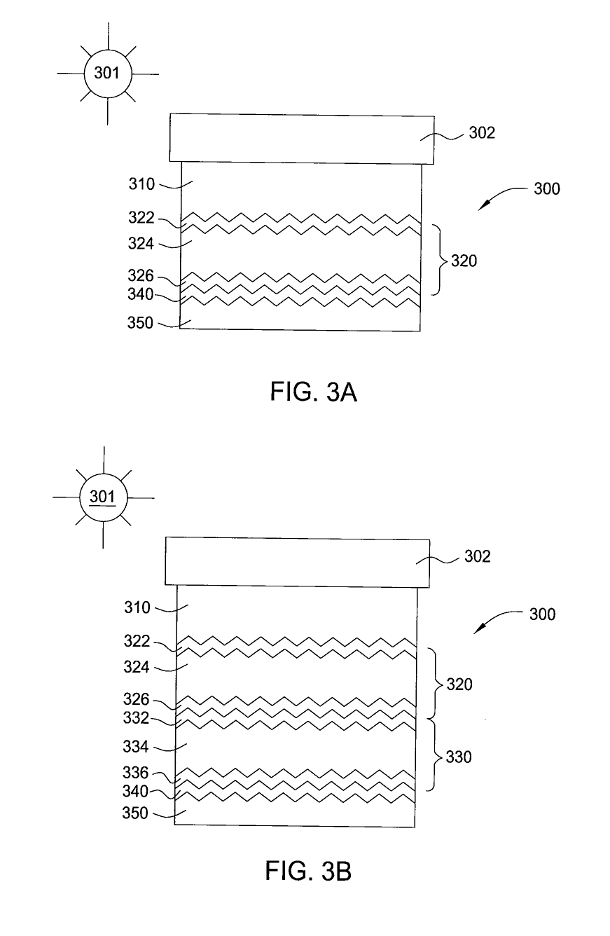

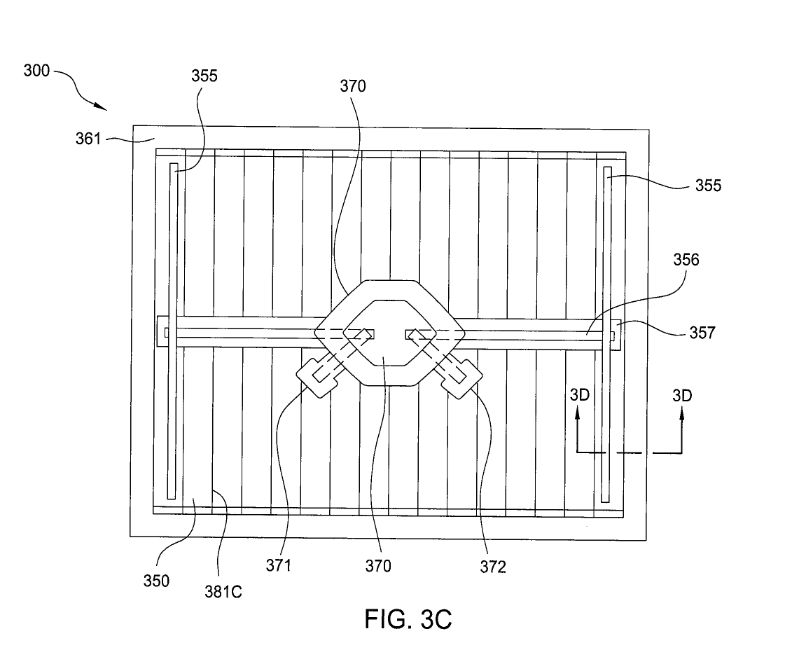

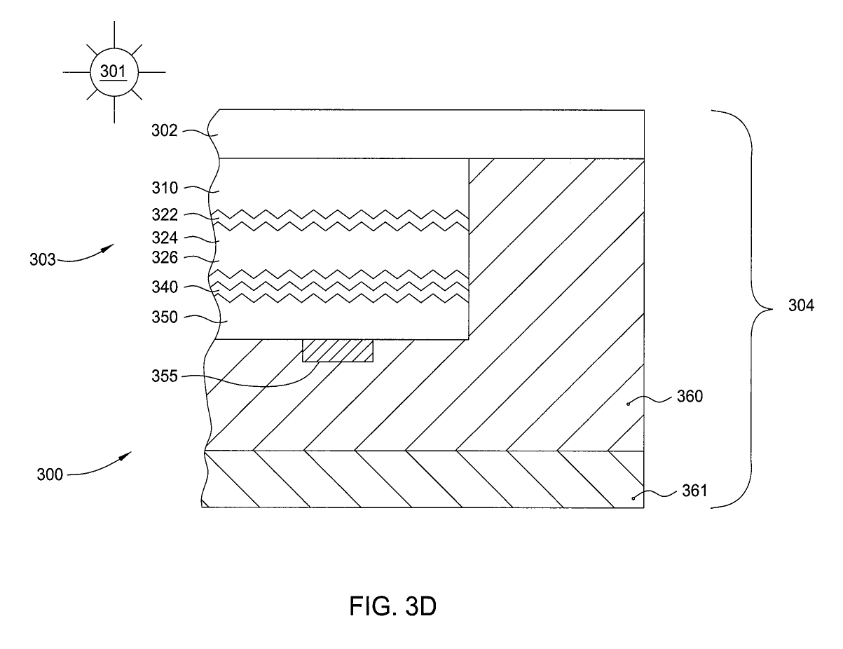

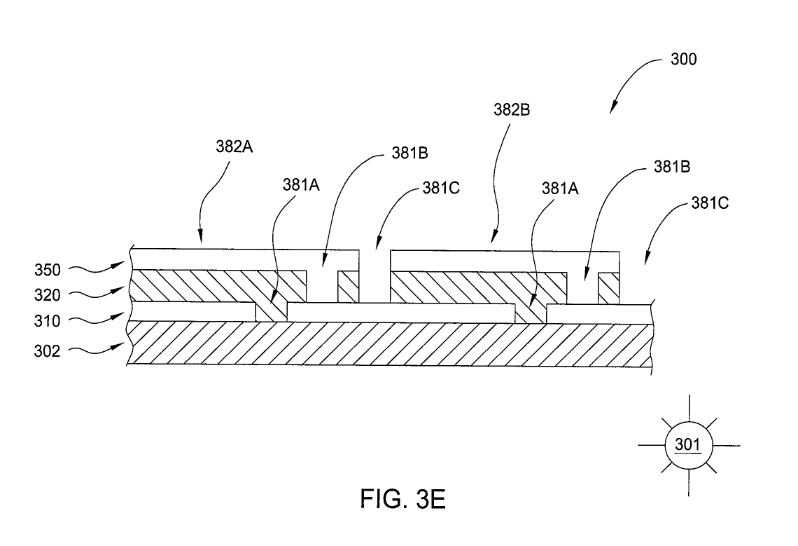

Examples of a solar cell 300 that can be formed using the process sequence(s) illustrated in FIG. 1 and the components illustrated in the solar cell production line 200 are illustrated in FIGS. 3A-3E. FIG. 3A is a simplified schematic diagram of a single junction amorphous or micro-crystalline silicon solar cell 300 that can be formed and analyzed in the system described below. As shown in FIG. 3A, the single junction amorphous or micro-crystalline silicon solar cell 300 is oriented toward a light source or solar radiation 301. The solar cell 300 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 300 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it. In one configuration, the first p-i-n junction 320 may comprise a p-type amorphous silicon layer 322, an intrinsic type amorphous silicon layer 324 formed over the p-type amorphous silicon layer 322, and an n-type amorphous silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type amorphous semiconductor layer 326 may be formed to a thickness between about 100 Å and about 500 Å. The back contact layer 350 may include, but is not limited to a material selected from the group consisting of Al, Ag, Ti, Cr, Au, Cu, Pt, alloys thereof, and combinations thereof.

FIG. 3B is a schematic diagram of an embodiment of a solar cell 300, which is a multi-junction solar cell that is oriented toward the light or solar radiation 301. The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340. In the embodiment shown in FIG. 3B, the first TCO layer 310 is textured, and the subsequent thin films deposited thereover generally follow the topography of the surface below it. The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline semiconductor layer 326 may be formed to a thickness between about 100 Å and about 400 Å. The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to a material selected from the group consisting of Al, Ag, Ti, Cr, Au, Cu, Pt, alloys thereof, and combinations thereof.

FIG. 3C is a plan view that schematically illustrates an example of the rear surface of a formed solar cell 300 that has been produced in the production line 200. FIG. 3D is a side cross-sectional view of portion of the solar cell 300 illustrated in FIG. 3C (see section 3D-3D). While FIG. 3D illustrates the cross-section of a single junction cell similar to the configuration described in FIG. 3A, this is not intended to be limiting as to the scope of the invention described herein.

As shown in FIGS. 3C and 3D, the solar cell 300 may contain a substrate 302, the solar cell device elements (e.g., reference numerals 310-350), one or more internal electrical connections (e.g., side buss 355, cross-buss 356), a layer of bonding material 360, a back glass substrate 361, and a junction box 370. The junction box 370 may generally contain two connection points 371, 372 that are electrically connected to portions of the solar cell 300 through the side buss 355 and the cross-buss 356, which are in electrical communication with the back contact layer 350 and active regions of the solar cell 300. To avoid confusion relating to the actions specifically performed on the substrates 302 in the discussion below, a substrate 302 having one or more of the deposited layers (e.g., reference numerals 310-350) and/or one or more internal electrical connections (e.g., side buss 355, cross-buss 356) disposed thereon is generally referred to as a device substrate 303. Similarly, a device substrate 303 that has been bonded to a back glass substrate 361 using a layer of bonding material 360 is referred to as a composite solar cell structure 304.

FIG. 3E is a schematic cross-section of a solar cell 300 illustrating various scribed regions used to form the individual cells 382A-382B within the solar cell 300. As illustrated in FIG. 3E, the solar cell 300 includes a transparent substrate 302, a first TCO layer 310, a first p-i-n junction 320, and a back contact layer 350. Three laser scribing steps may be performed to produce trenches 381A, 381B, and 381C, which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. While a single junction type solar cell is illustrated in FIG. 3E this configuration is not intended to be limiting to the scope of the invention described herein.

### General Solar Cell Formation Process Sequence

Referring to FIGS. 1 and 2, the process sequence 100 generally starts at step 102 in which a substrate 302 is loaded into the loading module 202 found in the solar cell production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., first TCO layer 310) already deposited on a surface of the substrate 302 before it is received into the system in step 102. If a conductive layer, such as TCO layer, is not deposited on the surface of the “raw” substrates then a front contact deposition step (step 107), which is discussed below, needs to be performed on a surface of the substrate 302.

In one embodiment, the substrates 302 or 303 are loaded into the solar cell production line 200 in a sequential fashion, and thus do not use a cassette or batch style substrate loading system. In the next step, step 104, the surfaces of the substrate 302 are prepared to prevent yield issues later on in the process. In one embodiment of step 104, the substrate is inserted into a front end substrate seaming module 204 that is used to prepare the edges of the substrate 302 or 303 to reduce the likelihood of damage, such as chipping or particle generation from occurring during the subsequent processes.

Next the substrate 302 or 303 is transported to the cleaning module 205, in which step 105, or a substrate cleaning step, is performed on the substrate 302 or 303 to remove any contaminants found on the surface of thereof. Common contaminants may include materials deposited on the substrate 302 or 303 during the substrate forming process (e.g., glass manufacturing process) and/or during shipping or storing of the substrates 302 or 303. Typically, the cleaning module 205 uses wet chemical scrubbing and rinsing steps to remove any undesirable contaminants.

In the next step, or front substrate inspection step 106, the substrate 302 or 303 is inspected via an inspection module 206, and metrology data is collected and sent to the system controller 290. In one embodiment, the substrate 302 or 303 is optically inspected for defects, such as chips, cracks, inclusions, bubbles, or scratches that may inhibit performance of a fully formed solar cell device, such as the solar cell 300. In one embodiment, the optical characteristics of the substrate 302 are inspected via the inspection module 206 and metrology data is collected and sent to the system controller 290 for analysis and storage. In one embodiment, the optical characteristics of the TCO layer of the device substrate 303 is inspected by the inspection module 206 and metrology data is collected and sent to the system controller 290 for analysis and storage.

In the next step, or step 108, separate cells are electrically isolated from one another via scribing processes. Contamination particles on the TCO surface and/or on the bare glass surface can interfere with the scribing procedure.

Referring to FIGS. 1 and 2, in one embodiment, prior to performing step 108 the substrates 302 are transported to a front end processing module (not illustrated in FIG. 2) in which a front contact formation process, or step 107, is performed on the substrate 302. In one embodiment, the front end processing module is similar to the processing module 218 discussed below. In step 107, the one or more substrate front contact formation steps may include one or more preparation, etching and/or material deposition steps that are used to form the front contact regions on a bare solar cell substrate 302. In one embodiment, step 107 generally comprises one or more PVD steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more CVD steps are used to form the front contact region on a surface of the substrate 302.

Next the device substrate 303 is transported to the scribe module 208 in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process.

In one embodiment, the device substrate 303 may be optionally transferred into another inspection module 206, where a corresponding inspection step 106 may be performed on the device substrate 303 to detect any damage caused by handling devices within the scribe module 208 Next, the device substrate 303 is transported to an inspection module 209 in which a front contact isolation inspection step 109 is performed on the device substrate 303 to assure the quality of the front contact isolation step 108. The collected metrology data is then sent and stored within the system controller 290.

Next the device substrate 303 is transported to the cleaning module 210 in which step 110, or a pre-deposition substrate cleaning step, is performed on the device substrate 303 to remove any contaminants found on the surface of the device substrate 303 after performing the cell isolation step 108. Typically, the cleaning module 210 uses wet chemical scrubbing and rinsing steps to remove any undesirable contaminants found on the device substrate 303 surface after performing the cell isolation step. In one embodiment, a cleaning process similar to the processes described in step 105 above is performed on the device substrate 303 to remove any contaminants on the surface(s) of the device substrate 303.

In one embodiment, the device substrate 303 may be optionally transferred into another inspection module 206, where a corresponding inspection step 106 may be performed on the device substrate 303 to detect any damage caused by handling devices within the scribe module 208.

Next, the device substrate 303 is transported to the processing module 212 in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form one or more p-i-n junctions. In one embodiment, the one or more p-i-n junctions comprise amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303. In some embodiments, the processing tool could be a single chamber to deposit all p-i-n layers.

In one embodiment, the device substrate 303 is transferred to an accumulator 211A prior to being transferred to one or more of the cluster tools 212A-212D. In one embodiment, in cases where the solar cell device is formed to include multiple junctions, such as the tandem junction solar cell 300 illustrated in FIG. 3B, the cluster tool 212A in the processing module 212 is adapted to form the first p-i-n junction 320 and cluster tools 212B-212D are configured to form the second p-i-n junction 330. In such an embodiment, the device substrate 303 may optionally be transferred into a spectrographic inspection module 215 for a corresponding film characterization step 115 following processing in the first cluster tool 212A. In one embodiment, the optional inspection module 215 is configured within the overall processing module 212.

One embodiment of a spectrographic inspection module, such as the inspection module 215, as well as a method for inspecting properties on moving substrates, is subsequently described in more detail in the section entitled, “On-The-Fly Spectrographic Inspection System and Module.”

In the optional deposition film characterization step 115, the device substrate 303 is inspected via the inspection module 215, and metrology data is collected and sent to the system controller 290. In one embodiment, the device substrate 303 is spectrographically inspected to determine certain characteristics of the film deposited onto the device substrate 303, such as the variation in film thickness across the surface of the device substrate 303 and the band gap of the films deposited onto the device substrate 303.

In one embodiment, the device substrate 303 is passed through the inspection module 215 via the automation device 281. As the device substrate 303 passes through the inspection module 215, the device substrate 303 is spectrographically inspected, and data is captured and sent to the system controller 290, where the data is analyzed and stored.

In one embodiment, the inspection module 215 comprises an inspection region located below or above the device substrate 303 as it is transported by an automation device 281. In one embodiment, the inspection module 215 is configured to determine the exact positioning and velocity of the device substrate 303 as it passes therethrough. Thus, all data acquired from the inspection of the device substrate 303 by the inspection module 215 as a function of time may be placed within a positional reference frame relative to points found within regions of the device substrate 303. With this information, parameters such as film thickness uniformity across the surface of the device substrate 303 may be determined and sent to the system controller 290 for collection and analysis.

In one embodiment, the data received by the system controller 290 from the inspection module 215 are analyzed by the system controller 290 to determine whether the device substrate 303 meets specified quality criteria. If the specified quality criteria are met, the device substrate 303 continues on its path in the system 200 to the next station in the processing sequence. However, if the specified criteria are not met, actions may be taken to either repair the defect or reject the defective device substrate 303. In one embodiment, data collected by the inspection module 215 is captured and analyzed in a portion of the system controller 290 disposed locally within the inspection module 215. In this embodiment, the decision to reject a particular device substrate 303 may be made locally within the inspection module 215.

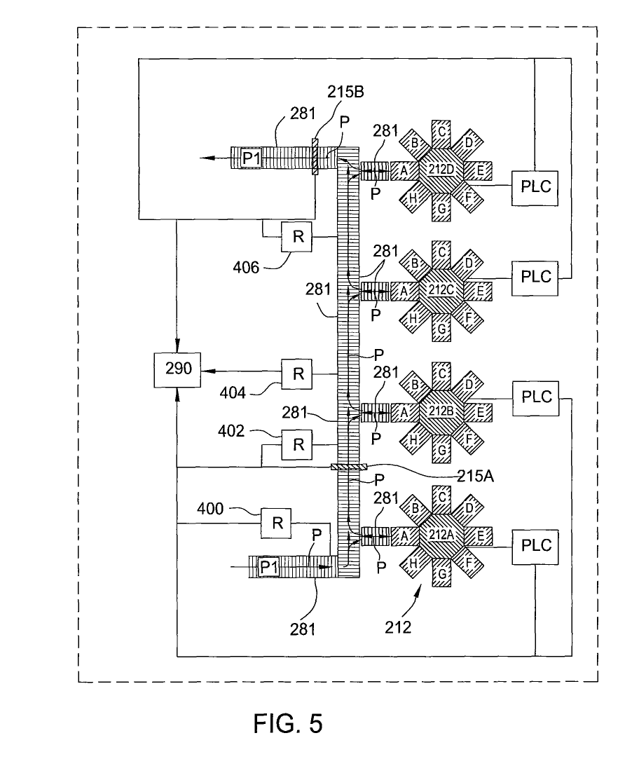

In one embodiment, the system controller 290 may analyze the information received from the inspection module 215 (e.g., reference numeral 215A in FIG. 5) to characterize the device substrate regarding certain film parameters. In one embodiment, the thickness and variation in thickness across the surface of the device substrates 303 may be measured and analyzed to monitor and tune the process parameters in the film deposition step 112. In one embodiment, the band gap of the deposited photovoltaic layers on the device substrates 303 may be measured and analyzed to monitor and tune the process parameters in the film deposition step 112 as well.

In one embodiment, the system controller 290 collects and analyzes the metrology data received from the inspection module 215 for use in determining the root cause of recurring defects in the device substrate 303 and correcting or tuning the preceding processes to eliminate the recurring defects. For instance, if the system controller 290 determines deficiencies in the film thickness are recurring in a specific film layer, the system controller 290 may signal that the process recipe for a specific process in step 112 may need to be refined. As a result the process recipe may be automatically or manually refined to ensure that the completed solar cell devices meet desired performance criteria.

In one embodiment of the process sequence 100, a cool down step, or step 113, is performed after step 112 has been performed. The cool down step is generally used to stabilize the temperature of the device substrate 303 to assure that the processing conditions seen by each device substrate 303 in the subsequent processing steps are repeatable. In one embodiment, the cool down step 113 is performed in one or more of the substrate supporting positions found in one or more accumulators 211.

In one configuration of the production line, as shown in FIG. 2, the processed device substrates 303 may be positioned in one of the accumulators 211B for a desired period of time to control the temperature of the device substrate 303. In one embodiment, the system controller 290 is used to control the positioning, timing, and movement of the device substrates 303 through the accumulator(s) 211 to control the temperature of the device substrates 303 before proceeding down stream through the production line.

In the next step, or deposition film inspection step 114, the device substrate 303 is inspected via an inspection module 214, and metrology data is collected and sent to the system controller 290. In one embodiment, the device substrate 303 is optically inspected for defects in the film layers deposited in step 112, such as pinholes, that may create a short between the first TCO layer 310 and the back contact layer 350 of a fully formed solar cell device, such as the solar cell 300. In one embodiment, the system controller 290 maps the defects detected in each device substrate 303, either locally or centrally, for use in metrology data analysis.

In the next step, or deposition film characterization step 115, the device substrate 303 is inspected via an additional inspection module 215, and metrology data is collected and sent to the system controller 290. In one embodiment, the device substrate 303 is spectrographically inspected to determine certain characteristics of the film deposited onto the device substrate 303, such as the variation in film thickness across the surface of the device substrate 303 and the band gap of the films deposited onto the device substrate 303.

In one embodiment, the device substrate 303 is passed through the inspection module 215 via the automation device 281. As the device substrate 303 passes through the inspection module 215, the device substrate 303 is spectrographically inspected, and data is captured and sent to the system controller 290, where the data is analyzed and stored.

In one embodiment, the inspection module 215 is an inspection region located below or above the device substrate 303 as it is transported by an automation device 281. In one embodiment, the inspection module 215 is configured to determine the exact positioning and velocity of the device substrate 303 as it passes therethrough. Thus, all data acquired from the inspection of the device substrate 303 by the inspection module 215 as a function of time may be placed within a positional reference frame relative to points found within regions of the device substrate 303. With this information, parameters such as film thickness uniformity across the surface of the device substrate 303 may be determined and sent to the system controller 290 for collection and analysis.

In one embodiment, the data received by the system controller 290 from the inspection module 215 (e.g., reference numeral 215B in FIG. 5) are analyzed by the system controller 290 to determine whether the device substrate 303 meets specified quality criteria. If the specified quality criteria are met, the device substrate 303 continues on its path in the system 200 to the next station in the processing sequence. However, if the specified criteria are not met, actions may be taken to either repair the defect or reject the defective device substrate 303. In one embodiment, data collected by the inspection module 215 is captured and analyzed in a portion of the system controller 290 disposed locally within the inspection module 215. In this embodiment, the decision to reject a particular device substrate 303 may be made locally within the inspection module 215.

In one embodiment, the system controller 290 may analyze the information received from the inspection module 215B to characterize the device substrate regarding certain film parameters. During manufacture of a tandem junction solar cell 300 illustrated in FIG. 3B, the inspection module 215A may analyze the properties of the first p-i-n junction 320 deposited on the TCO layer in cluster tool 212A such as thickness uniformity, TCO roughness, and crystalline fraction. After the second p-i-n junction 330 is formed on the first p-i-n junction 320 in any of cluster tools 212B-212D, the inspection module 215B be used to characterize the properties of both p-i-n junctions 320, 330 and may calculate the properties of the entire film stack 320, 330, or even just the second p-i-n junction 330. Various process adjustments may then be made for the cluster tools 212A and 212B-D depending on the analysis of the properties that may be executed with the inspection modules 215A and 215B. In one embodiment, the thickness and variation in thickness across the surface of the device substrates 303 may be measured and analyzed to monitor and tune the process parameters in this part of the film deposition step 112. In one embodiment, the band gap of the deposited film layers on the device substrates 303 may be measured and analyzed to monitor and tune the process parameters in the film deposition step 112 as well. In one embodiment, metrology data collected in the two inspection modules 215A and 215B may be collected and compared in order to characterize the photovoltaic layers deposited on the device substrate 303 during the deposition step 112, particularly with respect to multi-junction cells (e.g., FIG. 3B). A more detailed discussion regarding this process is subsequently described in more detail in the section entitled, “On-The-Fly Spectrographic Inspection System and Module.”

In one embodiment, the system controller 290 collects and analyzes the metrology data received from each inspection module 215 for use in determining the root cause of recurring defects in the device substrate 303 and correcting or tuning the preceding processes to eliminate the recurring defects. For instance, if the system controller 290 determines deficiencies in the film thickness are recurring in a specific film layer, the system controller 290 may signal that the process recipe for a specific process in step 112 may need to be refined. As a result the process recipe may be automatically or manually refined to ensure that the completed solar cell devices meet desired performance criteria.

One embodiment of a spectrographic inspection module, such as the inspection module 215, as well as a method for inspecting properties on moving substrates, is subsequently described in more detail in the section entitled, “On-The-Fly Spectrographic Inspection System and Module.”

Next, the device substrate 303 is transported to the scribe module 216 in which step 116, or the interconnect formation step, is performed on the device substrate 303 to electrically isolate various regions of the device substrate 303 surface from each other. In step 116, material is removed from the device substrate 303 surface by use of a material removal step, such as a laser ablation process. As shown in FIG. 3E, in one embodiment, the trench 381B is formed in the first p-i-n junction 320 layers by used of a laser scribing process. In one embodiment, the solar cell production line 200 has at least one accumulator 211 positioned after the scribe module(s) 216. During production accumulators 211C may be used to provide a ready supply of substrates to the processing module 218, and/or provide a collection area where substrates coming from the processing module 212 can be stored if the processing module 218 goes down or can not keep up with the throughput of the scribe module(s) 216.

Next, the device substrate 303 may be transported to an inspection module 217 in which a laser inspection step 117 may be performed and metrology data may be collected and sent to the system controller 290. In one embodiment of the laser inspection step 117, as the substrate 303 passes through the inspection module 217, the substrate 303 is optically inspected, and images of the substrate 303 are captured and sent to the system controller 290, where the images are analyzed and metrology data is collected and stored in memory.

Next, the device substrate 303 is transported to the processing module 218 in which one or more substrate back contact formation steps, or step 118, are performed on the device substrate 303. In step 118, the one or more substrate back contact formation steps may include one or more preparation, etching, and/or material deposition steps that are used to form the back contact regions of the solar cell device. In one embodiment, the solar cell production line 200 has at least one accumulator 211 positioned after the processing module 218. During production, the accumulators 211D may be used to provide a ready supply of substrates to the scribe modules 220, and/or provide a collection area where substrates coming from the processing module 218 can be stored if the scribe modules 220 go down or can not keep up with the throughput of the processing module 218.

Next, the device substrate 303 is transported to an inspection module 219 in which an inspection step 119 is performed on the device substrate 303. In one embodiment, the sheet resistance of the back contact layer 350 is measure by the inspection module 219 and metrology date is collected, analyzed, and stored by the system controller 290. In one embodiment, optical reflective properties of the back contact layer 350 are measured by the inspection modules 219 and metrology data is collected, analyzed, and stored by the system controller 290.

Next, the device substrate 303 is transported to the scribe module 220 in which step 120, or a back contact isolation step, is performed on the device substrate 303 to electrically isolate the plurality of solar cells contained on the substrate surface from each other. In step 120, material is removed from the substrate surface by use of a material removal step, such as a laser ablation process. As shown in FIG. 3E, in one embodiment, the trench 381C is formed in the first p-i-n junction 320 and back contact layer 350 by use of a laser scribing process.

Next, the device substrate 303 may be transported to an inspection module 221 in which a laser inspection step 121 may be performed and metrology data may be collected and sent to the system controller 290. In one embodiment of the laser inspection step 121, as the substrate 303 passes through the inspection module 221, the substrate 303 is optically inspected, and images of the substrate 303 are captured and sent to the system controller 290, where the images are analyzed and metrology data is collected and stored in memory.

Next, the device substrate 303 is transported to the quality assurance module 222 in which step 122, or quality assurance and/or shunt removal steps, are performed on the device substrate 303 to assure that it meets a desired quality standard and, in some cases, corrects defects in the formed solar cell device. The quality assurance module measures a number of electrical characteristics of the device substrate 303, and the collected metrology data is then sent to and stored within the system controller 290.

In one embodiment, the device substrate 303 may be optionally transferred into another inspection module 206, where a corresponding inspection step 106 may be performed on the device substrate 303 to detect any damage caused by handling devices within the scribe module 220. In one embodiment, the substrate 303 is passed through the inspection module 206 via the automation device 281. In one embodiment of the inspection step 106, as the substrate 303 passes through the inspection module 206, the substrate 303 is optically inspected, and images of the substrate 303 are captured and sent to the system controller 290, where the images are analyzed and metrology data is collected and stored in memory.

Next, the device substrate 303 is optionally transported to the substrate sectioning module 224 in which a substrate sectioning step 124 is used to cut the device substrate 303 into a plurality of smaller device substrates 303 to form a plurality of smaller solar cell devices.

In one embodiment, the device substrate 303 may be optionally transferred into another inspection module 206, where a corresponding inspection step 106 may be performed on the device substrate 303 to detect any damage caused by handling devices within the scribe module 216 or the sectioning module 224. In one embodiment, the substrate 303 is passed through the inspection module 206 via the automation device 281. In one embodiment of the inspection step 106, as the substrate 303 passes through the inspection module 206, the substrate 303 is optically inspected, and images of the substrate 303 are captured and sent to the system controller 290, where the images are analyzed and metrology data is collected and stored in memory.

Referring back to FIGS. 1 and 2, the device substrate 303 is next transported to the seamer/edge deletion module 226 in which a substrate surface and edge preparation step 126 is used to prepare various surfaces of the device substrate 303 to prevent yield issues later on in the process.

Next the device substrate 303 is transported to the pre-screen module 227 in which optional pre-screen steps 127 are performed on the device substrate 303 to assure that the devices formed on the substrate surface meet a desired quality standard. Next the device substrate 303 is transported to the cleaning module 228 in which step 128, or a pre-lamination substrate cleaning step, is performed on the device substrate 303 to remove any contaminants found on the surface of the substrates 303 after performing steps 122-127.

In the next step, or substrate inspection step 129, the device substrate 303 is inspected via an inspection module 229, and metrology data is collected and sent to the system controller 290. In one embodiment, the device substrate 303 is optically inspected for defects, such as chips, cracks, or scratches that may inhibit performance of a fully formed solar cell device, such as the solar cell 300.

In one embodiment, the device substrate 303 passes through the inspection module 229 by use of an automation device 281. As the device substrate 303 passes through the inspection module 229, the device substrate 303 is optically inspected, and images of the device substrate 303 are captured and sent to the system controller 290, where the images are analyzed and metrology data is collected and stored.

In the next step, or edge inspection step 130, each device substrate 303 is inspected via an inspection module 230, and metrology data is collected and sent to the system controller 290. In one embodiment, edges of the device substrate 303 are inspected via an optical interferometry technique to detect any residues in the edge deletion area that may create shorts or paths in which the external environment can attack portions of a fully formed solar cell device, such as the solar cell 300.

Next the substrate 303 is transported to a bonding wire attach module 231 in which step 131, or a bonding wire attach step, is performed on the substrate 303. Step 131 is used to attach the various wires/leads required to connect the various external electrical components to the formed solar cell device. Typically, the bonding wire attach module 231 is an automated wire bonding tool that is used to form the numerous interconnects that are often required to form the large solar cells formed in the automated integrated solar cell production line 200. In one embodiment, the bonding wire attach module 231 is used to form the side-buss 355 (FIG. 3C) and cross-buss 356 on the formed back contact region (step 118). In this configuration the side-buss 355 may be a conductive material that can be affixed, bonded, and/or fused to the back contact layer 350 found in the back contact region to form a good electrical contact. The cross-buss 356, which is electrically connected to the side-buss 355 at the junctions, can be electrically isolated from the back contact layer(s) of the solar cell by use of an insulating material 357, such as an insulating tape. The ends of each of the cross-busses 356 generally have one or more leads that are used to connect the side-buss 355 and the cross-buss 356 to the electrical connections found in a junction box 370, which is used to connect the formed solar cell to the other external electrical components.

In the next step, step 132, a bonding material 360 (FIG. 3D) and “back glass” substrate 361 are prepared for delivery into the solar cell formation process (i.e., process sequence 100). The preparation process is generally performed in the glass lay-up module 232, which generally comprises a material preparation module 232A, a glass loading module 232B, a glass cleaning module 232C, and a glass inspection module 232D. The back glass substrate 361 is bonded onto the device substrate 303 formed in steps 102-131 above by use of a laminating process (step 134 discussed below). In general, step 132 requires the preparation of a polymeric material that is to be placed between the back glass substrate 361 and the deposited layers on the device substrate 303 to form a hermetic seal to prevent the environment from attacking the solar cell during its life. Referring to FIG. 2, step 132 generally comprises a series of sub-steps in which a bonding material 360 is prepared in the material preparation module 232A, the bonding material 360 is then placed over the device substrate 303, and the back glass substrate 361 is loaded into the loading module 232B. The back glass substrate 361 is washed by the cleaning module 232C. The back glass substrate 361 is then inspected by the inspection module 232D, and the back glass substrate 361 is placed over the bonding material 360 and the device substrate 303.

In the next sub-step of step 132, the back glass substrate 361 is transported to the cleaning module 232C in which a substrate cleaning step, is performed on the substrate 361 to remove any contaminants found on the surface of the substrate 361. In the next sub-step of step 132, the back glass substrate 361 is inspected via the inspection module 232D, and metrology data is collected and sent to the system controller 290. In one embodiment, the back glass substrate 361 is optically inspected for defects, such as chips, cracks, or scratches that may inhibit performance of a fully formed solar cell device, such as the solar cell 300. The prepared back glass substrate 361 is then positioned over the bonding material and partially device substrate 303 by use of an automated robotic device.

Next the device substrate 303, the back glass substrate 361, and the bonding material 360 are transported to the bonding module 234 in which step 134, or lamination steps are performed to bond the backside glass substrate 361 to the device substrate formed in steps 102-132 discussed above. The device substrate 303, the back glass substrate 361 and bonding material 360 thus form a composite solar cell structure 304 (FIG. 3D) that at least partially encapsulates the active regions of the solar cell device.

In one embodiment, the composite solar cell structure 304 may be optionally transferred into another inspection module 206, where a corresponding inspection step 106 may be performed on the composite solar cell structure 304 to detect any damage caused by handling devices within the bonding module 234. In one embodiment, the composite solar cell structure 304 is passed through the inspection module 206 via the automation device 281. In one embodiment of the inspection step 106, as the composite solar cell structure 304 passes through the inspection module 206, the composite solar cell structure 304 is optically inspected, and images of the composite solar cell structure 304 are captured and sent to the system controller 290, where the images are analyzed and metrology data is collected and stored in memory.

Next the composite solar cell structure 304 is transported to the autoclave module 236 in which step 136, or autoclave steps are performed on the composite solar cell structure 304 to remove trapped gasses in the bonded structure and assure that a good bond is formed during step 136.

In the next step, or lamination quality inspection step 137, the composite solar cell structure 304 is inspected via an inspection module 237, and metrology data is collected and sent to the system controller 290. In one embodiment, the composite solar cell structure 304 is passed through the inspection module 237 by use of an automation device 281. As the composite solar cell structure 304 passes through the inspection module 237, the composite solar cell structure 304 is optically inspected, and images of the composite solar cell structure 304 are captured and sent to the system controller 290, where the images are analyzed and metrology data is collected and stored.

Next the solar cell structure 304 is transported to the junction box attachment module 238 in which junction box attachment steps 138 are performed on the formed solar cell structure 304. The junction box attachment module 238, used during step 138, is used to install a junction box 370 (FIG. 3C) on a partially formed solar cell. The installed junction box 370 acts as an interface between the external electrical components that will connect to the formed solar cell, such as other solar cells or a power grid, and the internal electrical connections points, such as the leads, formed during step 131.

In one embodiment, the composite solar cell structure 304 may be optionally transferred into another inspection module 206, where a corresponding inspection step 106 may be performed on the composite solar cell structure 304 to detect any damage caused by handling devices within the junction box attachment module 238. In one embodiment, the composite solar cell structure 304 is passed through the inspection module 206 via the automation device 281. In one embodiment of the inspection step 106, as the composite solar cell structure 304 passes through the inspection module 206, the composite solar cell structure 304 is optically inspected, and images of the composite solar cell structure 304 are captured and sent to the system controller 290, where the images are analyzed and metrology data is collected and stored in memory.

Next the solar cell structure 304 is transported to the device testing module 240 in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells. Next the solar cell structure 304 is transported to the support structure module 241 in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site. Next the solar cell structure 304 is transported to the unload module 242 in which step 142, or device unload steps are performed on the substrate to remove the formed solar cells from the solar cell production line 200.

In one embodiment of the solar cell production line 200, one or more regions in the production line are positioned in a clean room environment to reduce or prevent contamination from affecting the solar cell device yield and useable lifetime. In one embodiment, as shown in FIG. 2, a class 10,000 clean room space 250 is placed around the modules used to perform steps 108-118 and steps 130-134.

### Control System Design

Embodiments of the present invention may also provide an automation system that contains one or more controllers that are able to control the flow of substrates, materials, and the allocation of processing chambers within the solar cell fabrication process sequence. The automation system may also be used to control and tailor the properties of each completed device formed in the system in real time. The automation system may also be used to control the startup and troubleshooting of the system to reduce substrate scrap, improve device yield, and improve the time to produce a substrate.

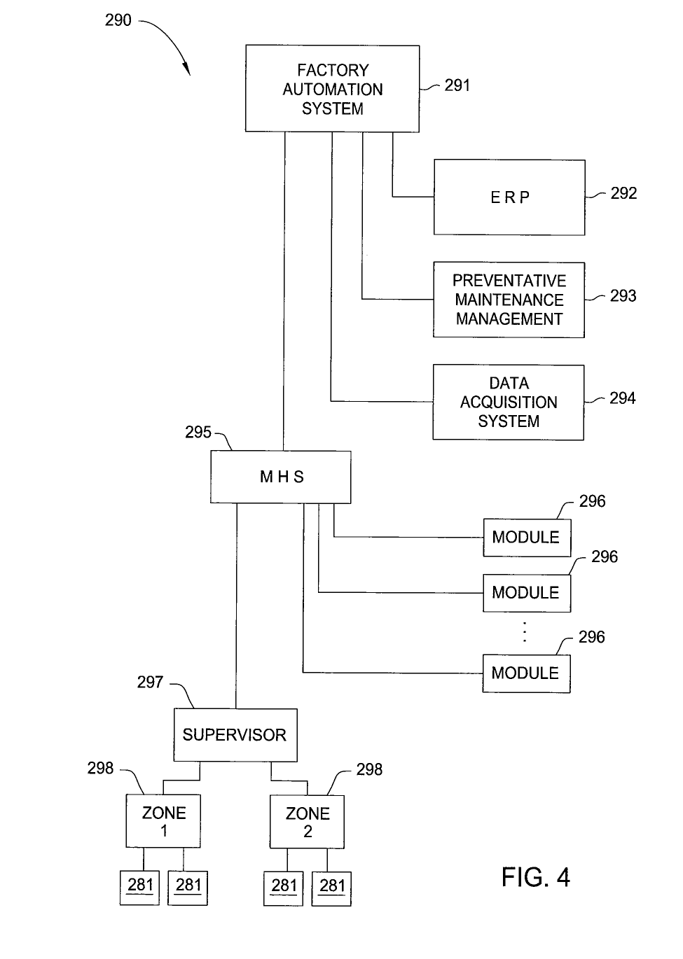

FIG. 4 is a schematic view of one embodiment of the various control features that may be contained within the system controller 290. In one embodiment, the system controller 290 contains a factory automation system (FAS) 291 that handles the strategic aspects of the substrate processing, and thus may control the dispatch of substrates into or through various parts of the system and the scheduling of various maintenance activities. The FAS thus is able to control and receive information from a number of components in the control architecture, such as a material handling/control system (MHS) 295, an enterprise resource (ERP) system 292, a preventive maintenance (PM) management system 293, and a data acquisition system 294. The FAS 291 generally provides complete control and monitoring of the factory, the use of feedback control, feed forward control, automatic process control (APC), and statistic process control (SPC) techniques, along with the other continuous improvement techniques to improve factory yield.

The MHS system 295 generally controls the actual movement and interface of various modules within the system to control the movement of one or more substrates through the system. The MHS system 295 will generally interface with multiple programmable logic controllers (PLCs) that each tasked with the movement and control of various smaller aspects of processing performed in the solar cell production line 200. The MHS and FAS systems may use feed forward or other automation control logic to control and deal with the systematic movement of substrates through the system. Since cost to manufacture solar cells is generally an issue, minimizing the capital cost of the production line is often an important issue that needs to be addressed. Therefore, in one embodiment, the MHS system 295 utilizes a network of inexpensive programmable logic controllers (PLCs) to perform the lower level control tasks, such as controlling the one or more of the automated devices 281, and controlling the one or more of the modules 296 (e.g., junction box attachment module 238, autoclave module 236) contained in the production line 200. Use of this configuration of devices also has an advantage since PLCs are generally very reliable and easy to upgrade. In one example, the MHS system 295 is adapted to control the movement of substrates through groups, or zones 298, of automated devices 281 by use of commands sent from the MHS system and delivered through supervisor controller 297, which may also be a PLC type device.

The ERP system 292 handles the various financial and support type functions that arise during the production of solar cell devices. The ERP system 292 can be used to ensure that the each module is available for use at a desired time within the production sequence. The ERP system 292 may control and advise the users of various current and upcoming support type issues in the production line. In one embodiment, the ERP system 292 has the capability to predict and order the various consumable materials used within the production sequence. The ERP system 292 may also be used to review, analyze, and control the throughput of the system to improve profit margins on the formed devices. In one embodiment the ERP system 292 is integrated with SAP to order and control of the management of consumable materials, spares, and other material related issues.

The (PM) management system 293 is generally used to control the scheduling and taking down of various elements in the system to perform maintenance activities. The PM management system 293 can thus be used to coordinate the maintenance activities being performed on adjacent modules in the production line to assure that down time of the production line, or branch of the production line, can be minimized. In one example, it may be desirable to take down cluster tool 212B and its associated inlet automation device 281 to reduce the unnecessary down time of both parts when either component separately removed from service. The PM management system 293 and ERP system 292 can generally work together to assure that all of the spare parts and other consumable elements have been ordered and are waiting for the maintenance staff when the preventive maintenance activity is ready to be performed.

In one embodiment, the FAS 291 is also coupled to a data acquisition system 294 that is adapted receive, store, analyze and report various process data received from each of the processing tools, in-line metrology data, offline metrology data and other indicators that are useful to assure that the processes being performed on the substrates are repeatable and within specification. The input and output data that is collected from internal inputs/sensors or from external sources (e.g., external systems (ERP, remote source)) is analyzed and distributed to desired areas of the solar cell production line and/or is integrated in various areas of the process sequence to improve the cycle time, system or chamber availability, device yield and efficiency of the process. One embodiment provides the use of factory automation software for the control of a photovoltaic cell manufacturing facility. The automation will provide WIP data storage and analysis and serial number tracking and data storage. The software will also have the ability to perform data mining to improve yield and link with the company ERP to assist in forecasting, WIP planning, sales, warranty claim payment and defense, and cash flow analysis.

### On-the-Fly Spectrographic Inline Inspection System and Module

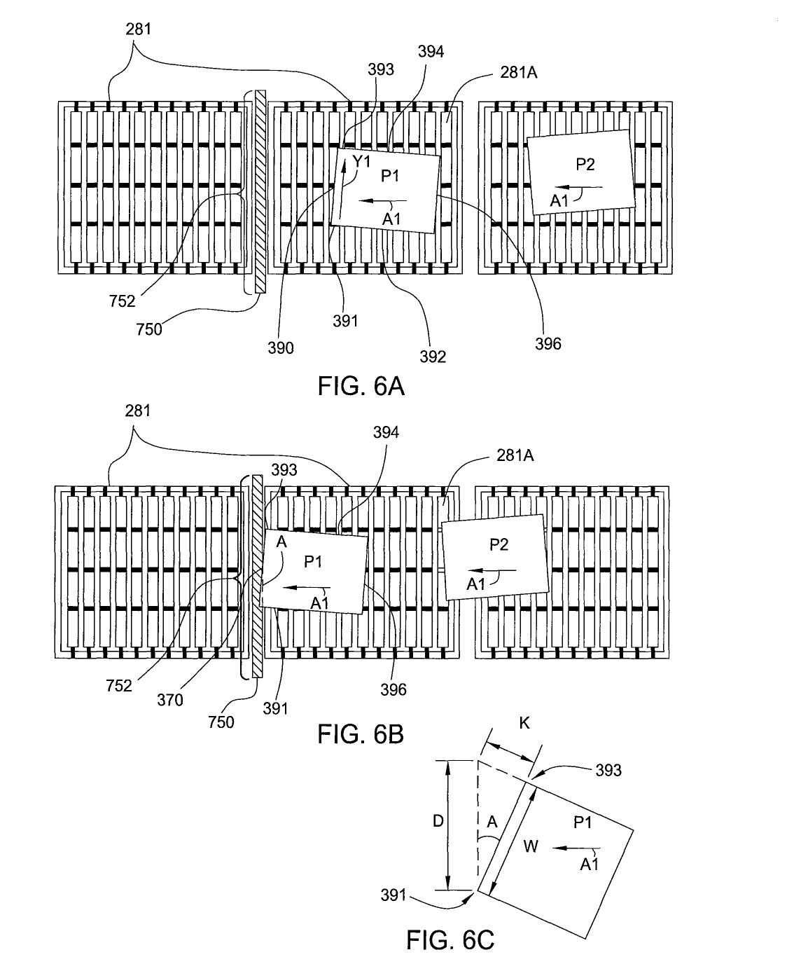

FIG. 5 illustrates in more detail a plan view of a portion of a solar cell production line shown in FIG. 2 and an automated inline inspection system for inspecting properties on a moving substrate. FIGS. 6-12 refer generally to various aspects of and methods of using the on-the-fly spectrographic inline inspection system and module.

In one embodiment of the invention, an inline inspection system within a solar cell production line includes a first substrate reader 400 positioned upstream from a cluster tool 212A, which has at least one processing chamber, such as processing chambers A-H. Any of processing chamber A-H may be adapted to deposit photovoltaic layers, e.g. a silicon-containing layer on a surface of the substrate, such as the one or more regions of a p-i-n junction comprising amorphous silicon and/or microcrystalline silicon materials.

The system also includes a characterization module 215A positioned downstream from one or more cluster tools, such as tool 212A, and positioned to receive a moving substrate having a silicon-containing layer deposited thereon. The characterization module 215A is configured to measure on-the-fly one or more properties of one or more deposited layers, e.g. photovoltaic layers, on the surface of the substrate. For example, the characterization module 215 may measure properties such as film thickness, film roughness, and film crystalline fraction. Moreover, not only can it measure these properties, but the characterization module may measure properties of many different photovoltaic layers at once and/or from the collected data calculate the properties of one or more of the inspected photovoltaic layers. For example, the one or more deposited photovoltaic layers may include transparent conductive oxide (TCO) films and silicon doped p-i-n junction layer films where the film characterization may measure and/or calculate the properties of those layers.

In another embodiment, the system includes a second characterization module 215B (FIG. 5) disposed in the solar cell production line 200 downstream from the one or more cluster tools, such as cluster tools 212B, 212C or 212D, and the first characterization module 215A. In one example, the second characterization module 215B is also upstream of the scribe module 216. The characterization modules 215A and 215B comprise a light source 750 and at least one spectral imaging sensor 730 wherein the at least one spectral imaging sensor 730 is configured to receive on-the-fly any of reflected, refracted, and/or transmitted light as illustrated by light beam 755 from an illuminated substrate P1 as it passes between the light source 750 and the at least one spectral imaging sensor 730. For example, the first and second characterization modules may employ one or more mirrors that are adapted to direct any of reflected, refracted, and/or transmitted light beam 755 to the spectral imaging sensor 730. Thus, the characterization module folds light emanating from the light source 750 that passes through the illuminated substrate P1 to create a folding light beam 755, which the spectral imaging sensor 730 receives. In some embodiments, the folding light beam may be 2.6 meters long from approximately the light source 750 to the spectral imaging sensor 730. One or more properties of various photovoltaic layers are thereby measured on-the-fly, i.e. the properties of the various photovoltaic layers on the substrates are measured simultaneously as the substrates are transported along the automation device 281 to various stages within the solar cell production line 200. Additionally, each substrate may be measured immediately after deposition of any of the first and/or second silicon-containing layers.

The system also includes a system controller 290 in communication with the readers 400, 402, 404, and 406 the characterization modules 215A and 215B, and the cluster tools 212A-212D. Additionally, the system controller 290 is configured to analyze information received from the any of the first and second characterization modules 215A and 215B. In one embodiment the system controller may take corrective action based on the received information. For example, the characterization modules may send information such as various measured properties to a local controller (PLC) and/or the system controller 290. After which, the system controller 290 may adjust one or more upstream processes based on the analyzed parameters.

In another embodiment, an inline inspection system includes a first processing tool 212A to deposit a top photovoltaic junction 320 on a substrate surface in a solar cell production line 200. A first characterization module 215A is positioned downstream from the first processing tool 212A to measure the properties of the top photovoltaic junction 320. A second processing tool, for example any of 212B-212D may be used to deposit a bottom photovoltaic junction 330 on the substrate surface. A second characterization module 215B is positioned downstream from the first processing tool 212A, the first characterization module 215A, and the second processing tool, for example any of 212B-212D, to measure the properties of the bottom photovoltaic junction 330. A system controller 290 is in communication with the first and second characterization module 215A, 215B and the one or more processing tools 212A-212D, where the system controller is configured to analyze information received from the first and second characterization module 215A, 215B.

FIGS. 6A and 6B are a plan view of substrates P1 and P2 that are positioned on an automation device 281 that is configured to deliver the substrates P1 and P2 over a light source 750 of a characterization module (not shown in this figure) according to one embodiment described herein. FIG. 6C illustrates an orientation a substrate may have while traversing the automation device 281. The substrate P1 however is shown without the automation device 281 to better illustrate the screw angle A and distance K between the leading corner and the trailing corner, which are discussed in more detail below. The substrates P1 and P2 are moved along the automation device 281 from one process to the next, such as the processes used to deposit a first p-i-n junction 320 and then the processes used to deposit a second p-i-n junction 330. The regions of the substrate disposed within an inspection area 752 created within the characterization module 215 can be inspected in a stripwise fashion. Therefore, at any instant in time, or at some desired frequency, as the substrate is delivered between the light source 750 and spectral imaging sensor 730 by the automation system 281, the characterization module 215 is adapted to deliver information regarding the properties of the substrate to the system controller 290. The light source 750 may be positioned between two automation devices 281 or simply placed beneath and between two rollers of an automation device 281.

In one embodiment of the characterization module 215, it is desirable to assure that the inspection area 752 is always disposed at an angle relative to the a leading edge 390 of a substrate to assure that light emanating from the light source is not occluded by the entire leading edge 390 at the same time. Rather, only a portion of the leading edge 390 will occlude light emanating from the light source at the beginning of the inspection process. In another embodiment, it is desirable to assure that the leading edge 390 is always disposed at an angle relative to the inspection area 752 for similar reasons above. As the inspection process is initiated by the occlusion of light emanating from the light source, having only a portion of the leading edge occlude light and thus initiate the inspection process, improves the inspection system's ability to calculate the position and velocity of the substrate, measure the optical properties of the film at specific inspection points along the substrate, and calculate specific properties.

In one example, the substrates P1 and P2, such as device substrate 303 referred to previously, are moving in a direction indicated by the arrows A1 and may be placed on the automation device 281 without complete alignment and thus approach the light source 750 at an angle. Alternatively, the light source 750 may be positioned at an angle relative to all substrates being transferred by the automation device 281 as the substrates P1 and P2 are passed over the inspection area 752. The spectral imaging sensor 730 of the characterization module 215 may inspect a linearly arranged strip of inspection points that may include a continuous or quasi-continuous strip of data collection points or locations along the substrate that are used to detect characteristics across the inspection area 752. Quasi-continuous indicates that there are many or enough inspection points along the length of the inspection area 752 such that a desired area of the substrate is inspected, such a strip of the substrate extending across the width of the substrate (e.g., Y1 direction in FIG. 6A), so that a desired resolution can be achieved for the application described here.

FIG. 10, subsequently discussed in more detail, shows one pattern 910 of various inspection points 900 that may be used in one embodiment of the invention as the substrate P1 travels over the light source 750. As the substrate P1 passes over the inspection area 752, the inspection module 215 spectrographically inspects each inspection point 900 (FIG. 10) on the substrate in the Y1 direction at that instant in time, and analyzes the optical properties of the film at each inspection point 900 located on the substrate in the Y1 direction. Thus, at the next instant in time as the substrate P1 continues to pass over the inspection area 752, another set of inspection points 900 are inspected, eventually forming a pattern of inspection points 910 along the substrate P1 when the substrate P1 has passed completely through the inspection area 752. Furthermore, by placing the inspection points in the same pattern on substrate P1, the inspection module 215 may assure inspection points are consistently done and can keep track of the substrate position over the light source, yielding consistent data results.

In the one embodiment, the strip of inspection points found in the inspection area 752 are arranged such that they are essentially perpendicular to the direction of substrate motion indicated by the arrows on the substrates P1 and P2. The edges of the substrates include a leading edge 390, trailing edge 396, port edge 392, and starboard edge 394. The inspection system is able to differentiate which parts of the light source are occluded by the presence of the substrate because the signal from each inspection point along the inspection area 752 is sensitive to the presence or absence of the substrate. Since the characterization module 215 generally operates in a continuous fashion, acquiring a signal from the inspection points along the inspection area as a time series, the inspection system would be able to determine the characteristics of the substrate at any point in time, i.e. when, the substrate begins to cover the inspection points in the inspection area 752.

To improve solar cell quality, it is important to collect data along the manufacturing process to quickly catch a problem such as if a production tool drifts out of the process parameters, so as to not waste materials and time. In one example, it is important to measure the thickness variation of the p-i-n junctions as they are manufactured to insure thickness uniformity. Other properties such as crystalline fraction of the various layers help to determine if a layer is amorphous or microcrystalline in structure. The physical topology of the various layers may be measured and the data used to adjust any process parameters of previous deposition systems. As the leading edge 390 of P1 begins to pass over the light source, the inspection points along the inspection area will be (event 1) occluded at the leading corner 391 of the leading edge 390, then (event 2) along the length between the leading corner 391 of the leading edge 390 to the trailing corner 393 of the leading edge 390, and then (event 3) at the trailing corner 393 of the leading edge 390. Therefore, by knowing the elapsed time “T” between the event 1 and event 3″, the characterization module 215 is able to determine the length of the substrate's leading edge W (FIG. 6C), and the distance between the point where the two corners 391 and 393, leading and trailing, cross the inspection light source 390 is D. Thus, the angle of skew, A, from normal, where the leading edge 390 is perpendicular to the light source direction, is given by the ARCCOSINE of D divided by W. Thus, the skew of the substrate may be measured. The length by which the leading corner 391 leads the trailing corner 393, K, is given by D multiplied by the COSINE of A. The velocity of the substrate on the automation device 281, V, may then be established as K divided by T. Thus, an external aligning system may be unnecessary to measure the film characteristics of the substrate.

Once the above parameters, absolute position, angle A, and velocity V are determined, all data acquired from the inspection points within the inspection area and/or along the length of the inspection area 752 as a time series may be placed within the reference frame of the substrate using a series of coordinate transforms which are functions of the above parameters. This allows valuable information such as uniformity across the solar cell substrate of inspected film parameters such as thickness of a film deposited in a previous step of the fabrication process. Additionally, the inspection system will have similar sensitivity to the position within the inspection area 752 of the port and starboard edges 392, 394 of the substrate P1. In similar ways, given dense enough inspection points along the inspection area 752 and an angle A sufficiently different than zero, the position, angle, and velocity of the substrate P1 may be continuously monitored and refined as the substrate passes by the inspection area 752. In one embodiment, the entire substrate surface is measured and/or the substrate edges and corners are measured.

In cases where the angle A is small, the inspection area 752 may be oriented at an angle, such as 5 or 10 degrees from parallel, for example, in order to create the condition that the leading corners of the leading and trailing edges always cross the inspection area 752 sufficiently before the trailing corners of the leading and trailing edge. Thus, the two corners of the leading edge will cross the inspection area 752 at different times. Similarly, the two corners of the trailing edge will cross the inspection area 752 at different times. In other words, the inspection area 752 may be positioned at an angle relative to the rollers 281A (e.g., rolling direction A1) of automation device 281 and not parallel to the automation device 281. The calculations may be adjusted to take into account the small additional angle. Thus, the calculations are similar but different depending on the angle A. In his way, the important parameters absolute position, angle, and velocity of the substrate may still be determined. In one embodiment, the inspection area 752 is desirably configured to have the following: 1) The inspection area 752 is wider than the width of the substrate P1; 2) The inspection points in the inspection area 752 may be have sufficient density to achieve a desired resolution; and 3) The inspection points in the inspection area 752 may be configured to measure properties continuously or quasi-continuously across the inspection area. Thus, one advantage of this inline inspection system is that it can measure properties regardless of the substrate velocity or orientation along the automation device 281. The inspection area 752 is thus able to provide, substrate angle A and substrate velocity V to determine the optical properties of the film deposited on the substrate.

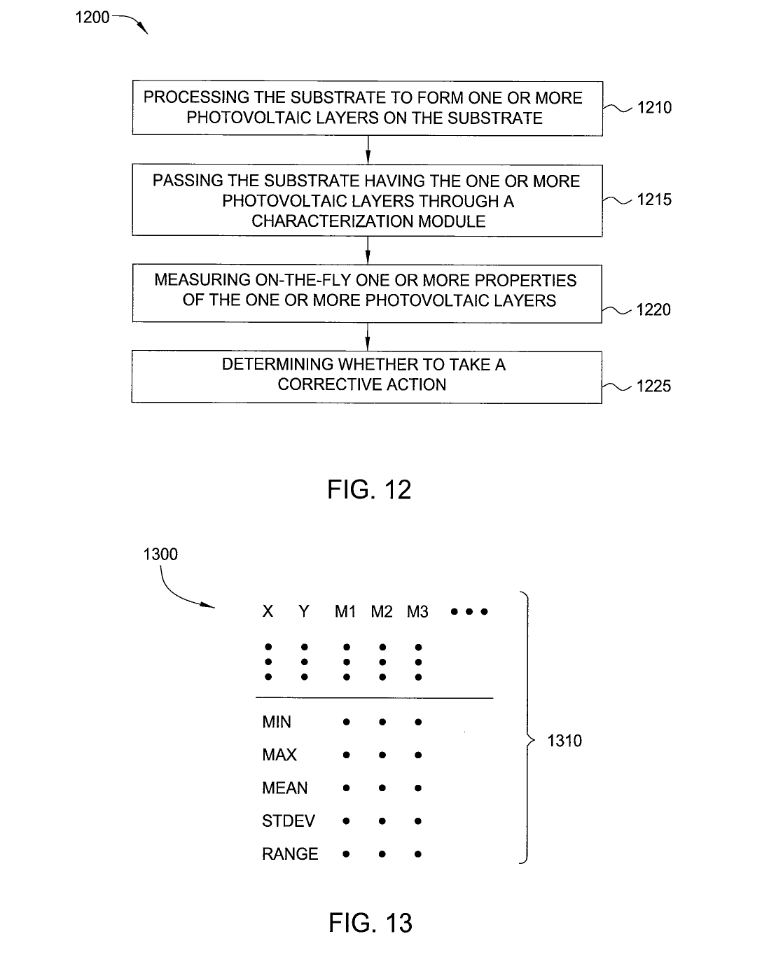

FIG. 12 illustrates a method 1200 used to inspect a substrate in a solar cell production line according to one embodiment described herein. A method 1200 for inspecting a substrate (e.g., substrate P1) in a solar cell production line 200 includes processing the substrate to form one or more photovoltaic layers on the substrate 1210, passing the substrate having the one or more photovoltaic layers through a characterization module 1215. Next, the method includes measuring on-the-fly one or more properties of the one or more photovoltaic layers 1220 and determining whether to take a corrective action 1225.

In one embodiment, determining whether to take a corrective action further comprises sending the time-wise measured properties to a system controller, storing the measured properties in the system controller, calculating theoretical properties of the one or more photovoltaic layers based on known process parameters of the processing tool, comparing the measured properties to the theoretical properties, and adjusting the process parameters of the processing tool.

In one embodiment, the collected property data of an inspected substrate includes a data array, wherein each of the data points in the data array have an x and y coordinate corresponding to a measured location or inspection data point on the substrate. In one embodiment, the data array also includes a statistical analysis of the measured properties. It should be noted that the information in the data array may be created by illuminating a moving substrate with a light source; and receiving on-the-fly refracted, reflected, and transmitted light from regions of the moving substrate using a spectral imaging sensor; and analyzing the optical properties of the received light to determine various properties.

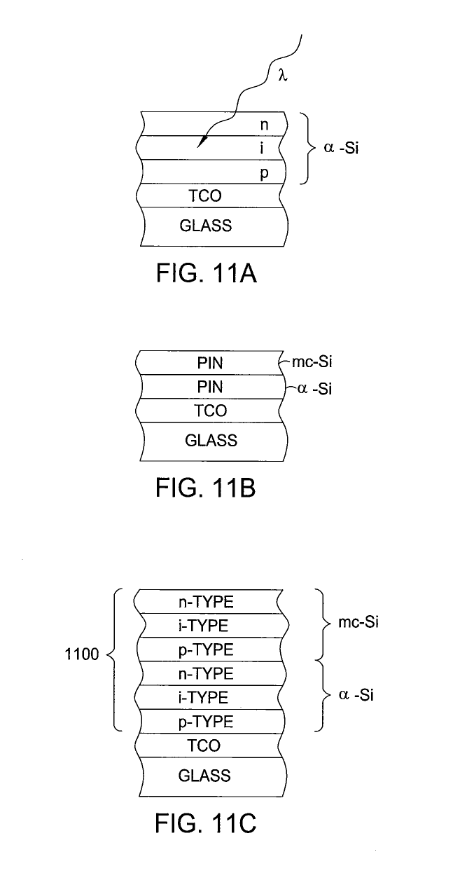

To better illustrate the above method, reference will also be made to previously discussed Figures and FIGS. 10-13. FIG. 10 depicts an exemplary measurement pattern on a moving substrate according to one embodiment described herein. FIGS. 11A-11C depict a schematic partial cross-sectional view of photovoltaic layers on a substrate that are inspected according to one embodiment described herein.

In one embodiment of the production line 200, a reader 400 is configured to communicate with the system control 291 at a position within the production line 200 before the first cluster tool 212A. The system control 291 then informs the PLC of cluster tool 212A that P1 is on its way. As the substrate P1 arrives at the cluster tool 212A, the PLC of cluster tool 212A records which process chamber(s) A-D are used to deposit a silicon-containing film on the substrate P1. FIG. 11A shows an example of one substrate after a p-i-n doped amorphous-silicon film layer is deposited over a TCO layer. The amorphous-silicon film layer may be the first silicon containing layer deposited on the surface of substrate P1. As P1 exits the cluster tool 212A, the system controller 290 tells the characterization module 215 that substrate P1 is on its way. As the substrate P1 passes through the characterization module 215, the measured properties are sent to the system controller 290 and are stored locally with the substrate ID collected in the reader 400 for P1.

As the characterization module 215 measures the properties of any of the photovoltaic layers, a data array may be formed corresponding measurement points along at least one direction (e.g., x and y direction) across the substrate P1 as depicted in FIG. 13, which shows one embodiment of the data array. For example, the inspection module 215 may measure properties anywhere along the substrate you want as depicted in FIG. 10. For instance, one measurement pattern may include a series of inspection points 900 that form two diagonals along the substrate P1 and multiple inspection points within the four quadrants formed by the two diagonals.

As the properties at each inspection point are measured along the substrate, a data point is created in the data array which is stored in the system controller. Each data point includes an X and Y coordinate location on the substrate corresponding to each of the physical inspection point measured on the substrate P1 (see FIG. 10). Thus, the discrete inspection points along the inspection area are swept across the substrate to inspect specific points 900 along the substrate. Then the measured properties M1, M2, M3, etc. for each X, Y location on the substrate are recorded. Thus, each single inspection point on the substrate P1 has a corresponding data point 1300 of X, Y, M1, M2, M3, etc., where, in one example, M1 may be film thickness, M2 film roughness, and M3 film crystalline fraction. As each data point is measured for each inspection location 900 on the substrate, they are recorded in a data array 1310 as shown in FIG. 13. Below the data points, various statistics are also recorded such as Minimum, Maximum, Mean, Standard Deviation (STDEV), and Range. Thus the inspection module 215 calculates the statistics of various measurement points and communicates that data with the system controller 290. The system controller 290 then calculates the theoretical properties based on known process parameters of the cluster tool 212A.

In one embodiment, the system controller 290 has stored in memory, or is able to poll any of its distributed controllers, the process parameters (PP) for each process chamber A-H of cluster tool 212A. For example the system controller 290 knows the deposition rate and deposition time for the particular process recipe being used. The system controller 290 calculates the theoretical properties based on known PP. For example, the system controller may calculate the theoretical thickness of the first silicon-containing layer, such as the p-i-n doped amorphous-silicon film depicted in FIG. 11A. The system controller then compares the actual measured film property and compares it to the theoretical film property, such as comparing actual film thickness and compared film thickness.

After comparison, the system controller calculates a delta PP which is the difference between the theoretical and measured properties. The system controller then adjusts the process parameters of the cluster tool 212A. It does so by sending the delta PP back to the PLC that is in communication with the cluster tool 212A. The PLC knows in which process chamber A-H of cluster tool 212A substrate P1 was processed by searching its database. The system controller 290 thereby performs a supervisory function by monitoring the process results and sending appropriation information to the PLC to control the process parameters.

The following example may illustrate the supervisory relationship between the system controller 290 and the PLC. Once the system controller locates the process chamber A-H that P1 went through, the PLC can adjust the process parameters of the appropriate process chamber A-H to maintain appropriate properties such as uniform film thickness across the area of the substrate. For example with film thickness, the PLC can give corrective action by adjusting the deposition residence time for appropriate chamber A-H as it receives feedback from the system controller 290 based on the measured substrates from inspection module 215. This system controller feedback and inspection system enables the system controller to keep properties in spec for all substrates even as cluster tools 212A-212D may naturally drift in and out of process parameters. Thus, substrate yield is greatly improved by helping to maintain uniform properties such as thickness. Additionally, a reader 400, 402, 404, and 406 is positioned in upstream from of each cluster tool 212A-212D, so that if a substrate comes into the characterization module 215 out of order, the system controller 290 will help figure out where each substrate is located along the production line 200.

Although the previous example was explained with regards to measuring the properties of the substrate P1 as it comes out of cluster tool 212A and into characterization module 215A, combinations of same methods may be used to inspect a substrate leaving a second cluster tool 212B-212D by use of the characterization module 215B. As previously discussed herein, a first silicon-containing layer is formed over a TCO layer on a glass substrate, as shown in FIG. 11A. A second silicon-containing layer may be formed over the first silicon-containing layer. For example, a p-i-n doped microcrystalline silicon layer may be formed over the p-i-n doped amorphous silicon layer in any of cluster tools 212B-212D as shown in FIG. 11B. FIG. 11C simply shows the configuration of each p-i-n layer within the two silicon-containing layers and forming a tandem junction type solar cell. Also shown in FIG. 11A is light lambda that passes through the various layers for the inspection module.

In one embodiment of the invention, a characterization module 215B is positioned after cluster tool 212D to measure the properties, using inspection techniques as performed in characterization module 215A. However, the data collected by the characterization module 215B is actually more complicated due to the increase in the number of layers formed on the substrate surface. In one embodiment, one method of overcoming this complication is to take the film property measurements of the first p-i-n or amorphous silicon layer and subtracting the collected total measurements of the both the first and second silicon containing layers collected in the characterization module 215B. For example, as shown in FIG. 11C, the total thickness 1100 is measured in inspection module 215B and the previously recorded amorphous silicon film thickness is subtracted from the total to yield the film thickness of the microcrystalline silicon film. Then the feed back loop is initiated again where the system controller 290 compares the second silicon-containing layer film thickness with its theoretical thickness based on the process parameters of the particular cluster tool 212B-212D in which the substrate P1 was processed. The delta PP is calculated and also sent to the system and so that the process parameters may be adjusted accordingly for the particular process chamber A-H in which the substrate was processed. In some embodiments, the inspection system may only utilize characterization module 215B positioned after all the deposition or processing modules 212A-212D. Thus, the properties of the total film stack including the amorphous and microcrystalline silicon film layers as well as the TCO layer may be measured. For example, the TCO roughness may be measured along with amorphous silicon film thickness and crystalline fraction.

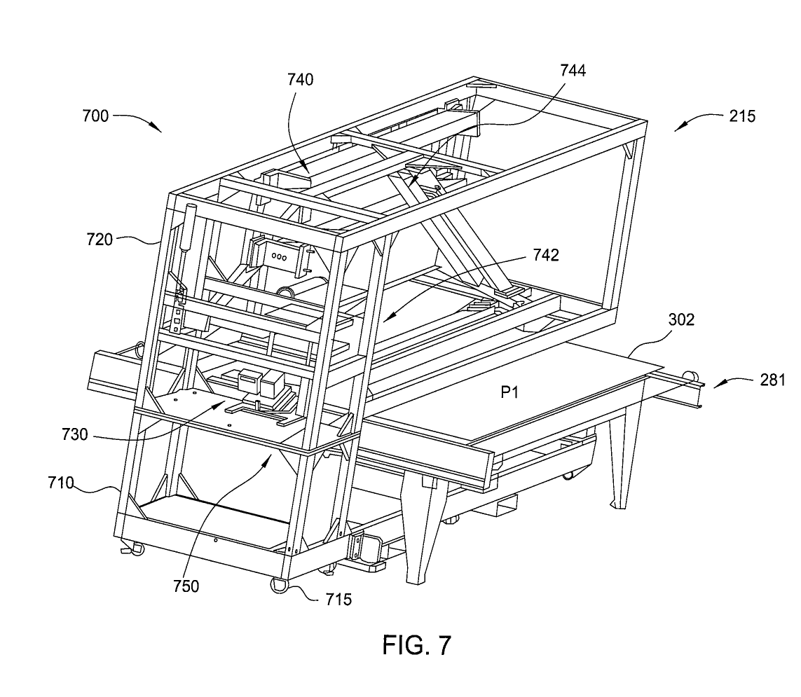

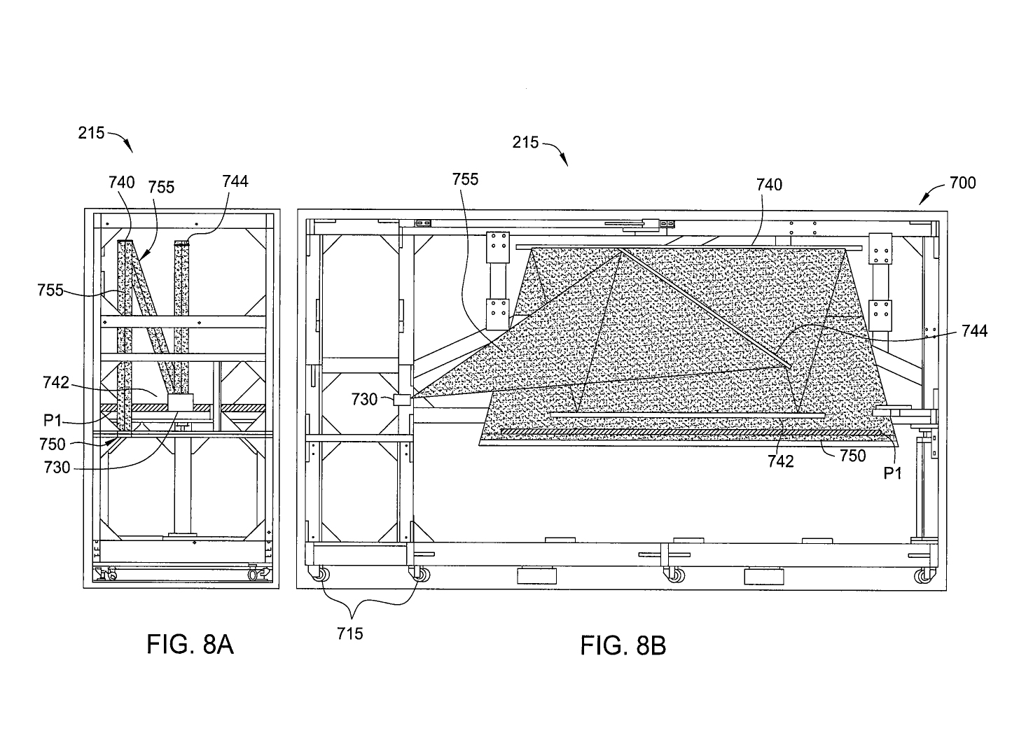

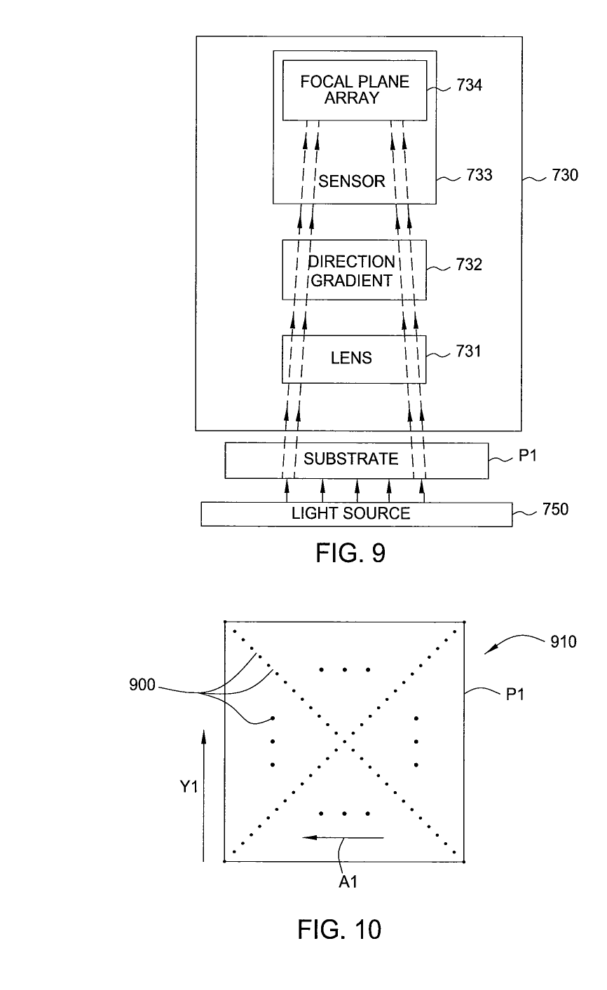

FIG. 7 is a schematic, isometric view of a characterization module 215 such as the spectrographic inspection modules 215A and 215B according to one embodiment described herein. FIG. 8A is a side view of a characterization module as depicted in FIG. 7, and FIG. 8B is another side view of the characterization module as depicted in FIG. 7. FIG. 9 is a schematic depiction of the light transmitted from the light source 750 to the spectral imaging sensor 730.

In one embodiment, the characterization module includes a housing frame 700 configured to be positioned along an automated solar cell production line such as automation device 281 of production line 200. A light source 750 is attached to the frame 700 and configured to illuminate substrates P1 on-the-fly as they are conveyed through the inspection area 752 by an automation device 281. In one embodiment, a light beam 755, which is wider than the substrate P1, may emanate from the light source 750. Alternatively, multiple sources of light may also be used instead a single light source e.g. multiple discrete light sources arranged to illuminate the substrates. Additionally, the light source 750 may comprise any type of electromagnetic radiation source capable of illuminating the substrate P1 for inspection thereof. For example, the light source 750 may include both visible and invisible electromagnetic radiation such as infrared or ultraviolet electromagnetic radiation. In one embodiment, the wavelength of light emitted from the light source 750 may be controlled to provide optimum optical inspection conditions. In one embodiment, a broad range of light wavelength may be emitted from the light source 750. In one embodiment, the spectrographic inspection module 215 comprises one or more cameras, such as CCD cameras, and other supporting components that are used to spectrographically inspect various regions of the substrate P1 on-the-fly. In one embodiment, the characterization module 215 comprises a plurality of spectral imaging sensors 730 positioned at the end of the light path from light source 750, such that the substrate P1 may be translated between the spectral graphic imaging sensor 730 and the light source 750. In one embodiment, the spectrographic inspection module 215 is in communication with the system controller 290.

The module 215 also includes at least one spectral imaging sensor 730 attached to the frame 700 and configured to receive on-the-fly any of reflected, refracted, and transmitted light beam 755 from an illuminated moving substrate P1 as shown in FIGS. 7, 8A, and 8B. The frame 700 may be mobile such as shown be the wheels 715. Additionally, the frame 700 may have multiple detachably connected sections, such as upper section 720 and lower section 710. This may enable assembly of the inspection module 215 on-site in the factory and provides greater mobility should it need to be positioned at a different location along the production line 200.

The characterization module 215 may include at least one mirror attached to the frame to direct the reflected, refracted, or transmitted light coming from the moving substrate and is received by at least one spectral imaging sensor. In one embodiment, the spectral imaging sensor 730 includes the use of multiple mirrors to direct the light beam 755 to the spectral imaging sensor 730. For example, three mirrors, an upper mirror 740, a lower mirror 742, and an angled mirror 744 may be used to direct the light beam 755 toward the spectral imaging sensor 730. The mirrors may need to be rigid and large thus requiring a rigid frame or structure to hold them. In this manner, the spectral imaging sensor 730 received folded light In one embodiment, the spectrographic inspection module 215 is positioned within the solar cell production line 200 to receive a substrate P1 from the automation device 281. The automation device 281 may feed the substrate P1 between the spectral imagine sensor 730 and the light source 750 as the substrate P1 is translated through the spectrographic inspection module 215. In one embodiment, as the substrate P1 is fed through the spectrographic inspection module 215, the substrate P1 is illuminated via the light source 750, while the spectral imagine sensor 730 receives on-the-fly reflected, refracted, or transmitted light from the substrate P1. The spectrographic inspection module 215 sends the optical properties and properties to the system controller 290, where the data are analyzed and metrology data is collected. In one embodiment, the data are retained by portions of the system controller 290 disposed locally within the spectrographic inspection module 215 for analysis. In one embodiment, the system controller 290 uses the information supplied by the spectrographic inspection module 215 to determine whether the substrate P1 meets specified criteria. The system controller 290 may then take specific action to correct any defects detected or reject the substrate P1 from the solar cell production line 200.

In one embodiment, the system controller 290 may use the information collected from the spectrographic inspection module 215 to diagnose the root cause of a recurring defect and correct or tune the process to minimize or eliminate the recurrence of the defect.

FIG. 9 schematically illustrates one embodiment of how light travels from the light source 750 through the substrate P1 to the spectral imaging sensor 730 in a spectrographic inspection module 215. In this configuration, light comes up through the substrate and is diffused along all different directions, while by use of mirrors and/or lenses disposed within the inspection module 215 the light leaving the substrate can be directed to a single optical inspection device. Light diffraction, interference and/or reflection is a function of wavelength of light, and thus the film disposed on the substrate affects the light that shines through the substrate. Thus, instead of one wavelength of light, many wavelengths shine though the substrate i.e. a broadband light source may be used to improve resolution and quality of data collected. As the light passes through the substrate, it reflects off the front surface, passes through a photovoltaic layer (i.e. transmission) and refracts. Light then hits the next interface and reflects, transmits through the next layer, and refracts. This process repeats as the light travels through the substrate P1 and the photovoltaic layers. The multitude of light beams that then exit the substrate and are collected by the spectral imaging sensor 730 can be analyzed by the system controller 290, and the wavelength and other received data (e.g., light intensity) can be analyzed and described by a power series which is convergent. Thus, the transmission coefficient may be calculated using Fresnel equations.

Fresnel equations indicate the percentage transmission is a function of many optical variables, such as thicknesses of various films, surface roughness, angle of light you used, index of different films and wavelength. Fresnel algorithms also take into account the angle at which the light enters the substrate and to make the calculations to determine the properties based on the optical properties of the processed substrate. A regression routing analysis may be used to solve for the variables when the percentage transmission is known, such as using a Levenberg-Marquardt algorithm or a simplex algorithm. Once the film index is calculated based on the percentage transmission, the crystal fraction may be calculated based on another function that correlates the different film index to crystal function

As part of a spectral imaging sensor 730 the light travels through a lens 731, a diffraction grating 732, and a sensor 733. The sensor 733 may comprise a focal plane array 734, which contains many photosensors that are arranged in an array pattern, such as a rectangular grid type array. In operation, the different wavelengths of light that pass through the layers formed on the substrate are distributed across different regions (e.g., columns) of the focal plane array due to the interaction of the light with the diffraction grating 732 disposed upstream of the focal plane array 734. The elements in the focal plane array 734 can be configured to receive discrete wavelengths of light, or wavelength bands, for example, at wavelengths between 600 nm and 1600 nm. As the data is collected as the substrate moves over the light source, the received time related information by the imaging sensor 730 also includes position information along the substrate. A set of data for each solar cell substrate, or a 3-dimensional data cube, can be formed. The data cube is generally one way to review and analyze the multi-variable data (e.g., X-position, Y-position, wavelength, and time) received from the inspection of each solar cell substrate. One will note that the data cube can be pictorially viewed as having one edge of the cube corresponding to the different wavelengths of light received by the focal plane array, another edge of the data cube corresponding to the locations X along the substrate received by the focal plane array (i.e., X direction is generally at an angle “A” relative to the inspection strip), and the third edge of the data cube corresponding to a location Y on the substrate (i.e., parallel to the transfer direction and perpendicular to the X-direction) as the substrate moves in direction Y as a function of time. Therefore, by use of the spectral imaging sensor 730 components and the automation hardware, which controls the movement of the substrate in the direction Y, a snapshot of one or more properties at each X and Y position at an instant in time can be collected. Certain wavelengths interact with certain films, so if you use one wavelength over time over various X spots, that may indicate how the thickness varies at the spot. The system controller will then compare the data collected to the theoretical properties for each substrate based on the process parameters used to process that particular substrate.

In another embodiment of the invention, instead of a wide light source used as part of the spectrographic inspection module, a smaller light source with many discrete sensors all in line may be used. For example, 5-7 discrete sensors may be used to get good measurements at the corners and the edges of the substrate.

One advantage of this inspection system as discussed herein and illustrated in FIG. 9 that utilizes a single inspection device that is positioned to receive all of the light emitted from a broad band source versus a more conventional fixed array of sensors is that the data collected by the system controller may miss an anomaly because only discrete parts of the substrate are illuminated and inspected by each sensor in a conventional sensor array. Thus, in the missing data found between the discrete parts of the substrate are blind spots. But with the embodiments of the invention, significantly more information is available because the entire substrate is illuminated. Additionally, the whole substrate may be inspected or the inspection pattern may be changed to inspect particular portions of the substrate. Embodiments of the invention also provide 100% sampling rate of all substrates and each substrate is measured immediately after deposition. Moreover, the system controller 290 may be used to define the desired points of inspection along the substrate. The optical transmission technique is sensitive to thickness and band-edge while insensitive to substrate alignment or vibration. Additionally, the entire substrate may be measured at 10 mm spatial resolution. Broad light wavelength range enables better metrology due to increased resolution, thus improving data collection.

While the foregoing is directed to embodiments of the present invention, other and further embodiments of the invention may be devised without departing from the basic scope thereof, and the scope thereof is determined by the claims that follow.

1. An inline inspection system comprising:
one or more processing tools;
a substrate reader positioned upstream from the one or more processing tools;
a characterization module positioned downstream from one or more processing tools, wherein the characterization module is configured to measure on-the-fly one or more properties of one or more photovoltaic layers formed on a substrate surface; and
a system controller in communication with the reader, the characterization module, and the one or more processing tools, the system controller configured to analyze information received from the characterization module.

2. The inline inspection system of claim 1, wherein the system controller is further configured to take corrective action based on the received information.

3. The inspection system of claim 2, wherein the characterization module comprises a light source and at least one spectral imaging sensor, and wherein the at least one spectral imaging sensor is configured to receive on-the-fly any of reflected, refracted, and transmitted light from an illuminated substrate as it passes between the light source and the at least one spectral imaging sensor.

4. The inspection system of claim 3, wherein the characterization module is configured to send information regarding the one or more photovoltaic layers to the system controller and adjust one or more upstream processes based on the analyzed parameters.

5. The inspection system of claim 4, further comprising a second characterization module comprising a light source and at least one spectral imaging sensor, wherein the second characterization module is disposed downstream from one or more processing tools and the characterization module, and wherein the second characterization module is configured to measure on-the-fly one or more properties of one or more photovoltaic layers formed on the substrate surface and is in communication with the system controller.

6. The inspection system of claim 5, wherein the second characterization module is configured to receive on-the-fly any of reflected, refracted, and transmitted light from an illuminated substrate having a first or a second silicon-containing layer thereon as it passes between the light source and the at least one spectral imaging sensor.

7. The inspection system of claim 5, wherein the second characterization module is configured to send information regarding the one or more photovoltaic layers to the system controller and adjust one or more upstream processes based on the analyzed parameters.

8. The inspection system of claim 7, wherein spectral imaging sensors of the characterization modules are programmed to determine one or more photovoltaic layer properties irrespective of substrate orientation or velocity.

9. The inspection system of claim 7, wherein each substrate is measured immediately after deposition of any of the photovoltaic layers.

10. The inspection system of claim 7, wherein the entire substrate surface is measured.

11. The inspection system of claim 7, wherein the substrate edges and corners are measured.

12. The inspection system of claim 7, wherein the characterization modules further comprise at least one mirror adapted to direct any of reflected, refracted, and transmitted light to the spectral imaging sensor.

13. The inspection system of claim 7, wherein the one or more properties of the one or more photovoltaic layers measured include film thickness, film crystalline fraction, and film roughness.

14. The inspection system of claim 7, wherein the one or more photovoltaic layers include transparent conductive oxide (TCO) films and silicon doped p-i-n junction layer films.

15. A characterization module, comprising:
a housing frame configured to be positioned along a solar cell production line;
a light source attached to the frame and configured to illuminate moving substrates on-the-fly as the substrates move along the solar cell production line; and
at least one spectral imaging sensor attached to the frame and configured to receive on-the-fly any of reflected, refracted, and transmitted light from an illuminated moving substrate.

16. The characterization module of claim 13, wherein the frame is mobile and further comprises multiple detachably connected sections.

17. The characterization module of claim 13, further comprising at least one mirror attached to the frame to direct light reflected, refracted, or transmitted from the illuminated moving substrate to the at least one spectral imaging sensor.

18. The characterization module of claim 13, wherein the light source emanates a light beam wider than the substrate.

19. A method for inspecting a substrate in a solar cell production line, comprising:
processing the substrate to form one or more photovoltaic layers on the substrate;
passing the substrate having the one or more photovoltaic layers through a characterization module;
measuring on-the-fly one or more properties of the one or more photovoltaic layers; and
determining whether to take a corrective action.

20. The method of claim 19 wherein determining whether to take corrective action further comprises:
sending the measured properties to a system controller;
storing the measured properties in the system controller;
calculating theoretical properties of the one or more photovoltaic layers based on known process parameters of a processing tool used to form the one or more photovoltaic layers on the substrate;
comparing the measured properties to the theoretical properties; and
adjusting the process parameters of the processing tool.

21. The method of claim 20, wherein the measured properties further comprise:
a data array comprising:
data points, each data point having an x and y coordinate corresponding to a measured location on the substrate and one or more measured properties at the particular x, y location on the substrate; and
statistical analysis of the measured properties.

22. The method of claim 19 wherein measuring on-the-fly further comprises:
moving the substrate along a solar cell production line while simultaneously illuminating the moving substrate with a light source; and
receiving any of refracted, reflected, and transmitted light from the illuminated moving substrate with a spectral imaging sensor; and
analyzing the optical properties of the received light to determine various properties of the one or more photovoltaic layers.

23. The method of claim 19, wherein the one or more properties measured of the one or more photovoltaic layers include thickness, crystalline fraction, and roughness.

24. The method of claim 19, wherein the one or more photovoltaic layers include transparent conductive oxide (TCO) films and silicon doped p-i-n junction layer films.

25. An inline inspection system, comprising:
a first processing tool to deposit a top photovoltaic junction on a substrate surface in a solar cell production line;
a first characterization module positioned downstream from the first processing tool to measure the properties of the top photovoltaic junction;
a second processing tool to deposit a bottom photovoltaic junction on the substrate surface;
a second characterization module positioned downstream from the first processing tool, the first characterization module, and the second processing tool to measure the properties of the bottom photovoltaic junction; and
a system controller in communication with the first and second characterization module and the one or more processing tools, the system controller configured to analyze information received from the first and second characterization module.
